(19) United States
(12) Patent Application Publication
(10) Pub. No.: US 2024/0429215 A1
(43) Pub. Date: Dec. 26, 2024

(54) SPLICING SCREEN, MANUFACTURING METHOD THEREOF, AND DISPLAY DEVICE

(71) Applicant: TCL China Star Optoelectronics Technology Co., Ltd., Shenzhen, Guangdong (CN)

(72) Inventor: Jhongciao KE, Shenzhen, Guangdong (CN)

(73) Assignee: TCL China Star Optoelectronics Technology Co., Ltd., Shenzhen, Guangdong (CN)

(21) Appl. No.: 17/621,764

(22) PCT Filed: Dec. 16, 2021
(86) PCT No.: PCT/CN2021/138843

§ 371 Date: Dec. 22, 2021

(30) Foreign Application Priority Data
Dec. 9, 2021 (CN) 202111501067.X

(51) Int. Cl. H01L 25/13; H01L 33/48

(52) U.S. Cl. CPC H01L 25/13; H01L 33/483; H01L 2933/0033

(57) ABSTRACT

In a splicing screen, a manufacturing method thereof, and a display device, the splicing screen includes a plurality of display modules. The display module includes: a plurality of packaged LED units including at least three first LED chips; a plurality of second LED chips; wherein a first distance between each second LED chip and an adjacent first LED chip is less than a second distance between the first LED chip in the packaged LED unit and the first LED chip in an adjacent packaged LED unit. A display performance of the splicing screen can be improved.

### FIELD OF INVENTION

The present application relates to the field of display technologies, and more particularly to a splicing screen, a manufacturing method thereof, and a display device.

### BACKGROUND OF INVENTION

Micro-LEDs (mini-LEDs or micro-LEDs) are becoming more and more popular due to their advantages of fast response, high color gamut, and low energy consumption.

In order to speed up a mass production of micro-LEDs or mini-LEDs, packaged LED chips (micro-LEDs in package, MIP) are used in micro-LEDs or mini-LEDs direct display displays. However, a display performance of a splicing part in an existing splicing screen is not good.

### Technical Problem

The display performance of the splicing part in the existing splicing screen is not good.

### SUMMARY OF INVENTION

Embodiments of the present application provide a splicing screen, a manufacturing method thereof, and a display device, so as to solve the problem of poor display performance at a splicing part in an existing splicing screen.

In a first aspect, an embodiment of the present application provides a splicing screen comprising a plurality of display modules that are spliced with each other, wherein each of the display modules comprises a display area and a splicing area located on at least one side of the display area, and each of the display modules comprises:
a plurality of packaged LED units disposed in the display area of the display module, wherein each packaged LED unit comprises at least three first LED chips;
a plurality of second LED chips disposed in the splicing area of the display module;
wherein in a splicing direction, there is a first distance between each of the second LED chips and the first LED chip of an adjacent packaged LED unit, there is a second distance between the first LED chip in the packaged LED unit and the first LED chip in the adjacent packaged LED unit, and the second distance is greater than the first distance.

Optionally, each of the packaged LED units comprises a package frame and three of the first LED chips, the three first LED chips are disposed in one row and three columns in the package frame, and a row direction of the three first LED chips is perpendicular to the splicing direction.

Optionally, the packaged LED units are disposed in an array of M rows and N columns, a row direction of the packaged LED units is perpendicular to the splicing direction, and at least three of the first LED chips in the packaged LED units in two adjacent rows are disposed in parallel.

Optionally, the second LED chips in the splicing area are arranged in an array of one row and K columns, and a row direction of the second LED chips is perpendicular to the splicing direction.

Optionally, each of the display modules comprises two splicing areas, and the two splicing areas are oppositely disposed on both sides of the display area.

Optionally, in the splicing direction, there is a third distance between the second LED chip in one of the splicing areas and the second LED chip in the splicing area of an adjacent display module, and the third distance is equal to the second distance.

In a second aspect, an embodiment of the present application further provides a display device, comprising:
a body; and
a splicing screen as described in any one of the above splicing screen, wherein the splicing screen is connected to the body.

In a third aspect, an embodiment of the present application further provides a method of manufacturing a splicing screen comprising:
packaging at least three first LED chips to obtain a packaged LED unit;
punching a plurality of the packaged LED units on a substrate;
disposing a plurality of second LED chips on at least one side of the plurality of packaged LED units to the substrate to obtain a display module;
splicing a plurality of the display modules so that in a splicing direction, there is a first distance between each of the second LED chips and the first LED chip of an adjacent packaged LED unit, there is a second distance between the first LED chip in the packaged LED unit and the first LED chip in the adjacent packaged LED unit, and the second distance is greater than the first distance.

Optionally, packaging the at least three first LED chips to obtain the packaged LED unit comprises:
arranging the three first LED chips in a row and three columns in a packaging frame to form the packaged LED unit, wherein a row direction of the three first LED chips is perpendicular to the splicing direction.

Optionally, punching the plurality of the packaged LED units on the substrate comprises:
arranging a plurality of the packaged LED units in an array of M rows and N columns, wherein a row direction of the plurality of packaged LED units is perpendicular to the splicing direction, and at least three of the first LED chips in the packaged LED units of two adjacent rows are arranged in parallel.

### Beneficial Effect

In the splicing screen, the manufacturing method thereof, and the display device of the embodiment of the present application, a single LED chip is arranged in the splicing area of the display module. This allows the distance between the LED chips in the splicing area of two adjacent display modules to be set to a required size without being affected by packaging. This makes spliced display images of the display modules uniform, thereby improving a display performance of the spliced screen. In addition, by disposing the packaged LED unit in the display area of the display module, compared to disposing a single LED chip in the display area, an assembly speed of the display module can be increased.

### DESCRIPTION OF DRAWINGS

In order to more clearly describe the technical solutions in the embodiments of the present application, the following will briefly introduce the drawings that need to be used in the description of the embodiments. Obviously, the drawings in the following description are only some embodiments of the present application. For those skilled in the art, without creative work, other drawings can be obtained based on these drawings.

In order to have a more complete understanding of the present application and its beneficial effects, the following description will be given in conjunction with the accompanying drawings. In the following description, the same reference numerals indicate the same parts.

FIG. 1 is a schematic diagram of a first structure of a display device provided by an embodiment of the application.

FIG. 2 is a schematic diagram of a second structure of a display device provided by an embodiment of the application.

FIG. 3 is a schematic structural diagram of a display module in the display device shown in FIG. 2.

FIG. 4 is a schematic flowchart of a method of manufacturing a splicing screen provided by an embodiment of the application.

### DETAILED DESCRIPTION OF PREFERRED EMBODIMENTS

The technical solutions in the embodiments of the present application will be clearly and completely described below in conjunction with the drawings in the embodiments of the present application. Obviously, the described embodiments are only a part of the embodiments of the present application, rather than all the embodiments. Based on the embodiments in this application, all other embodiments obtained by those skilled in the art without creative work shall fall within the protection scope of this application.

In order to solve the problem of poor display performance at a splicing location in the existing splicing screen, embodiments of the present application provide a splicing screen, a manufacturing method thereof, and a display device, which will be described below with reference to the accompanying drawings.

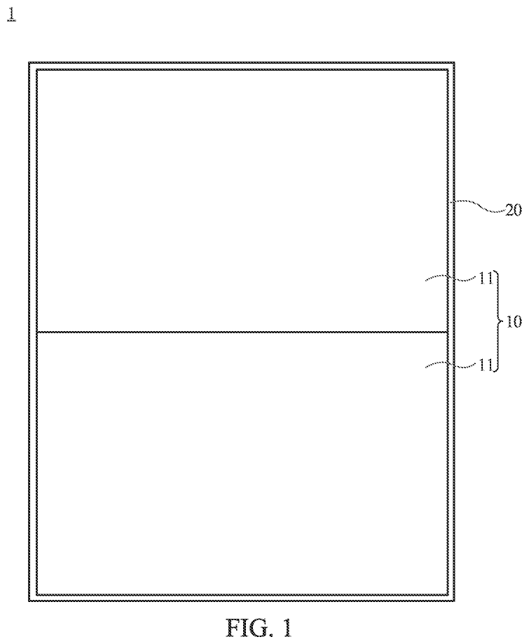

Exemplarily, please refer to FIG. 1, which is a schematic diagram of a first structure of a display device provided by an embodiment of the application. The embodiment of the present application provides a display device 1. The display device 1 may include a splicing screen 10 and a body 20. The splicing screen 10 is connected to the body 20. The body 20 is used to carry the splicing screen 10 and electrical components related to the splicing screen 10. It should be noted that different sizes of display devices 1 are usually used for different occasions. This makes an integration effect of the display device 1 and a use occasion better, and improves an aesthetics and a user's viewing comfort. For a large-sized display device 1, a large-sized display device 1 can be formed by splicing a plurality of display screens together.

The display device 1 may include a spliced screen 10 that has been spliced. A display performance of a splicing part in the existing splicing screen is poor, which makes a user experience poor. In order to solve the foregoing problems, an embodiment of the present application processes a splicing of the splicing screen 10 to improve the display performance of the splicing.

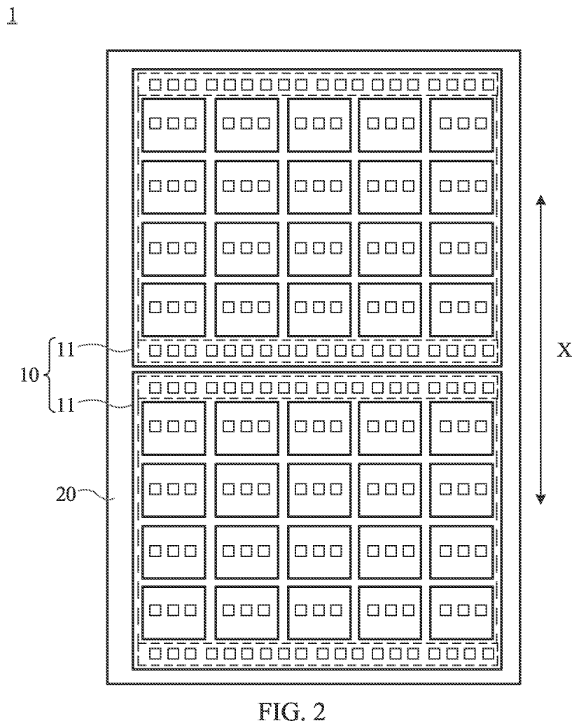

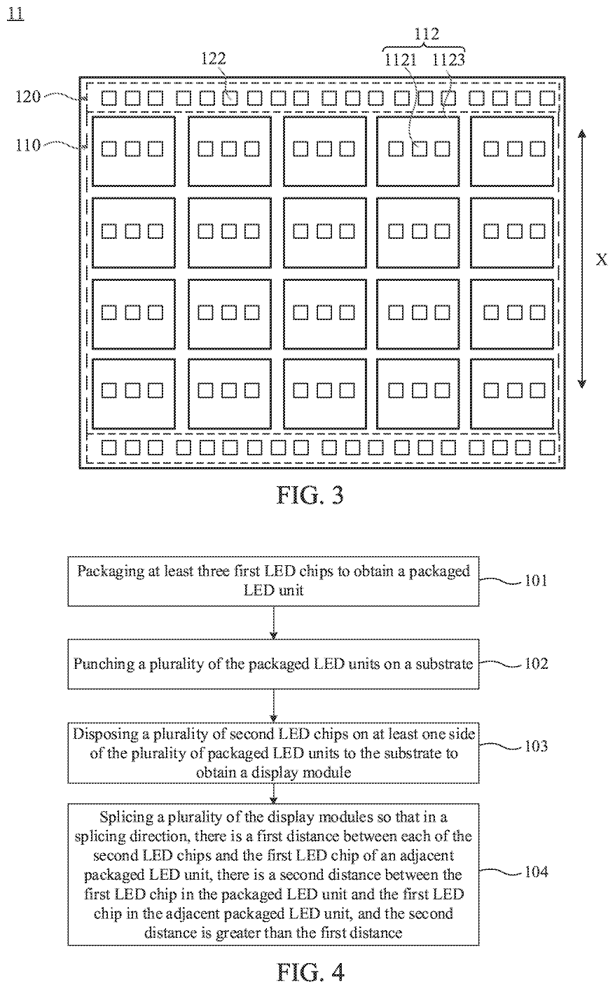

Exemplarily, please refer to FIG. 2 and FIG. 3 in conjunction with FIG. 1. FIG. 2 is a schematic diagram of a second structure of a display device provided in an embodiment of the application. FIG. 3 is a schematic structural diagram of a display module in the display device shown in FIG. 2. The splicing screen 10 of the embodiment of the present application includes a plurality of display modules 11 spliced with each other. Each display module 11 may include a display area 110 and a splicing area 120. The splicing area 120 is disposed on at least one side of the display area 110. That is, the splicing area 120 of one display module 11 is adjacent to another display module 11. Each display module 11 also includes a plurality of packaged LED units 112 and a plurality of second LED chips 122. A plurality of packaged LED units 112 are arranged in the display area 110 of the display module 11. Each packaged LED unit 112 includes at least three first LED chips 1121. The plurality of second LED chips 122 are arranged in the splicing area 120. In a splicing direction X, there is a first distance between each second LED chip 122 and the first LED chip 1121 of the adjacent packaged LED unit 112. There is a second distance between one first LED chip 1121 in one packaged LED unit 112 and the first LED chip 1121 in the adjacent packaged LED unit 112. The second distance is greater than the first distance. That is, a distance between each second LED chip 122 and the first LED chip 1121 of the adjacent packaged LED unit 112 is less than a distance between two first LED chips 1121 arranged oppositely in two adjacent packaged LED units 112. The splicing direction X is a direction in which the two display modules 11 face the splicing or back to a separation. By arranging a single LED chip in the splicing area 120 of the display module 11, this allows the distance between the LED chips in the splicing area 120 of two adjacent display modules 11 to be set to a required size without being affected by the packaging. This makes the spliced display images of the display module 11 uniform, thereby improving the display performance of the splicing screen 10. In addition, by disposing the packaged LED unit 112 in the display area 110 of the display module 11, compared to disposing a single LED chip in the display area, an assembly speed of the display module 11 can be increased.

It should be noted that the second LED chip 122 may be a mini-LED or a micro-LED, that is, a micro-light emitting diode. Micro-LED or mini-LED technology refers to a technology of a small-sized light-emitting diode (LED) array integrated on a substrate at a high density. The size of each micro-LED or mini-LED is only about 1 to 10 microns. Through this technology, a high-resolution micro-LED or mini-LED display panel can be formed. Micro-LED or mini-LED has the advantages of high luminous efficiency, low energy consumption, and high resolution.

Micro-LED or mini-LED usually uses direct display for display. In other words, one second LED chip 122 can display red light, green light, or blue light. Three second LED chips 122 displaying different colors can be used as one pixel unit. A plurality of pixel units exhibiting a certain arrangement and regular arrangement can display the picture. It should be noted that the direct display is relative to a backlight display. Backlight is a form of lighting in the electronics industry and is often used for LCD (liquid crystal display) displays. The biggest difference between liquid crystal and plasma is that liquid crystal should rely on a passive light source. The plasma TV is an active light-emitting display device. The mainstream LCD backlight technology on the market includes LED (light emitting diode) and CCFL (cold cathode fluorescent lamp). The light source may be an incandescent bulb, electro-optical panel (ELP), light emitting diode (LED), cold cathode tube (CCFL), etc. The electro-optical panel provides uniform light across the entire surface. Other backlight modules use diffusers to provide uniform light from uneven light sources. The backlight can be any color. Monochrome liquid crystals usually have backlights such as yellow, green, blue, and white. The color display uses white light because it covers the most shades.

Each display module 11 has at least one splicing area 120 along the splicing direction X. The plurality of second LED chips 122 in each splicing area 120 may be arranged in a row and K columns. The row direction of the plurality of second LED chips 122 is perpendicular to the splicing direction X. The three second LED chips 122 may serve as a pixel group. The display of the three second LED chips 122 is equivalent to the display of one packaged LED unit 112. Therefore, the K columns of the second LED chip 122 may be equivalent to three times the number of columns of the packaged LED unit 112.

Exemplarily, each display module 11 may include two splicing areas 120. The two splicing areas 120 are arranged opposite to two sides of the display area 110. In the splicing direction X, there is a third distance between the second LED chip 122 of one splicing area 120 and the second LED chip 122 of the splicing area 120 of the adjacent display module 11. The third distance and the second distance are equal. In other words, the distance between the second LED chip 122 of one splicing area 120 and the second LED chip 122 of the splicing area 120 of the adjacent display module 11 and the distance between one first LED chip 1121 in one packaged LED unit 112 and the first LED chip 1121 in the adjacent packaged LED unit 112 are equal. It is understandable that the second LED chip 122 of the splicing area 120 arranged in this way can make the display images of the two spliced display modules 11 uniform, and improve the user experience.

It should be noted that the first LED chip 1121 may be the same as the second LED chip 122. That is, the first LED chip 1121 may also be a mini-LED or a micro-LED. For the first LED chip 1121, reference may be made to the description of the second LED chip 122, which will not be repeated here.

The difference between the first LED chip 1121 and the second LED chip 122 is that the first LED chip 1121 is usually packaged for use to improve an assembly efficiency of the display module 11. It should be noted that at least three first LED chips 1121 may be packaged together to form a packaged LED unit 112. The packaged LED unit 112 may also be referred to as a MIP chip (micro-LED in package). At least three first LED chips 1121 are packaged together to form a unit. That is, the LED unit 112 is packaged. Then, a plurality of packaged LED units 112 are printed and arranged in the display area 110. Compared with arranging a plurality of single first LED chips 1121 in the display area 110, the method of arranging a plurality of packaged LED units 112 in the display area 110 in the embodiment of the present application can improve the assembly efficiency of the display module 11.

Exemplarily, each packaged LED unit 112 may include a package frame 1123 and three first LED chips 1121. The three first LED chips 1121 can respectively emit red light, green light, and blue light. Therefore, the three first LED chips 1121 that emit light of different colors can form a light-emitting unit or a pixel unit. Of course, the number of the first LED chips 1121 packaged in each packaged LED unit 112 can also be other numbers, which is not limited here. In the embodiment of the present application, each packaged LED unit 112 includes three first LED chips 1121 as an example for description.

Exemplarily, the three first LED chips 1121 may be arranged in a row and three columns in the package frame 1123. The row direction of the three first LED chips 1121 is perpendicular to the splicing direction X. In other words, the three first LED chips 1121 are arranged in a line in the package frame 1123. There is a predetermined interval between each first LED chip 1121. The three first LED chips 1121 may be arranged in a line from the middle position of one side of the packaging frame 1123 to the middle position of the other side of the packaging frame 1123 opposite to the aforementioned side. Of course, the three first LED chips 1121 can also be arranged in other ways. For example, the three first LED chips 1121 may be arranged in a triangle shape. For another example, the three first LED chips 1121 may also be arranged in oblique lines in the package frame 1123. That is, the straight line formed by the three first LED chips 1121 and the edge line of the package frame 1123 present a certain inclination angle, so as to meet different lighting requirements.

Exemplarily, the multiple packaged LED units 112 may be arranged in an array of M rows and N columns. The row direction of the plurality of packaged LED units 112 is perpendicular to the splicing direction X. At least three first LED chips 1121 in two adjacent rows of packaged LED units 112 are arranged in parallel. It can be understood that at least three first LED chips 1121 in two adjacent rows of packaged LED units 112 are arranged in parallel. The first LED chips 1121 in two adjacent rows of packaged LED units 112 are arranged in a line. The size of the package frame 1123 is greater than the size of the three first LED chips 1121 arranged together. Therefore, the distance between the first LED chips 1121 in two adjacent rows of packaged LED units 112 is greater than the distance between two adjacent first LED chips 1121 in two adjacent rows of packaged LED units 112.

In the splicing screen 10 of the embodiment of the present application, a plurality of single second LED chips 122 are arranged in the splicing area 120 of the display module 11. This allows the second LED chip 122 at the splicing site to be set to a required size without being affected by the package size. In turn, the display screen at the splicing site and the display screen in the display area 110 can be uniformly unified, thereby improving the display performance of the splicing screen 10 and improving the user experience. In addition, the packaged LED unit 112 is provided in the display area 110 of the display module 11. Compared with arranging a single LED chip in the display area, the packaged LED unit 112 of the embodiment of the present application can improve the assembly efficiency of the display module 11. On the whole, the splicing screen 10 of the embodiment of the present application can not only improve the display performance of the splicing, but also improve the assembly efficiency of the splicing screen 10, and has high compatibility.

It should be noted that, in the splicing screen 10 of the embodiment of the present application, two adjacent display modules 11 are detachably connected. That is, when the display device 1 is used, it can be used by splicing a plurality of display modules 11 together to form a splicing screen 10. When the display device 1 is not in use or when the display device 1 is being transported, the splicing screen 10 can be separated for the convenience of storage or transportation.

Exemplarily, the splicing screen 10 may be installed on the body 20. That is, the body 20 is used to connect a plurality of display modules 11. For example, the body 20 can be connected to the display module 11 from a side away from the display area 110. The body 20 may be a connecting plate with a larger size. Each display module 11 is arranged at a corresponding position of the body 20. For example, the body 20 may be provided with installation slots corresponding to the number of the display modules 11. When the display module 11 is installed in the installation slot, the splicing of the display module 11 is completed. The two display modules 11 are respectively connected to the connecting plate by, for example, screws, so that the two display modules 11 are spliced together. The splicing area 120 of two adjacent display modules 11 may also be bonded by adhesive tape. For example, when assembling, the display module 11 can be pre-fixed with adhesive tape. Then, the display modules 11 are connected together through the body 20. Of course, there can be other ways for the splicing of the display module 11, which will not be given as examples here.

Exemplarily, please refer to FIG. 1 to FIG. 3 and FIG. 4. FIG. 4 is a schematic flowchart of a method of manufacturing a splicing screen provided by an embodiment of the application. The embodiment of the present application also provides a method of manufacturing a splicing screen. For the structure of the splicing screen, refer to FIG. 1 to FIG. 3 and the above description, which will not be repeated here. The method of manufacturing the splicing screen includes the following:

Step 101: Packaging at least three first LED chips to obtain a packaged LED unit.

Exemplarily, each packaged LED unit 112 may include a package frame 1123 and three first LED chips 1121. The three first LED chips 1121 can respectively emit red light, green light, and blue light. Therefore, the three first LED chips 1121 that emit light of different colors can form a light-emitting unit or a pixel unit. Of course, the number of the first LED chips 1121 packaged in each packaged LED unit 112 can also be other numbers, which is not limited here. In the embodiment of the present application, each packaged LED unit 112 includes three first LED chips 1121 as an example for description.

Exemplarily, the three first LED chips 1121 may be arranged in a row and three columns in the package frame 1123. The row direction of the three first LED chips 1121 is perpendicular to the splicing direction X. In other words, the three first LED chips 1121 are arranged in a line in the package frame 1123. There is a predetermined interval between each first LED chip 1121. The three first LED chips 1121 may be arranged in a line from the middle position of one side of the packaging frame 1123 to the middle position of the other side of the packaging frame 1123 opposite to the aforementioned side.

Step 102: Punching a plurality of the packaged LED units on a substrate.

A plurality of packaged LED units 112 encapsulated with first LED chips 1121 are molded onto a substrate. The multiple packaged LED units 112 may be arranged in an array of M rows and N columns. The row direction of the packaged LED units 112 may be perpendicular to the splicing direction X. At least three first LED chips 1121 in two adjacent rows of packaged LED units 112 are arranged in parallel. It can be understood that at least three first LED chips 1121 in two adjacent rows of packaged LED units 112 are arranged in parallel. The first LED chips 1121 in two adjacent rows of packaged LED units 112 are arranged in a line. The size of the package frame 1123 is greater than the size of the three first LED chips 1121 arranged together. Therefore, the distance between the first LED chips 1121 in two adjacent rows of packaged LED units 112 is greater than the distance between two adjacent first LED chips 1121 in two adjacent rows of packaged LED units 112. The area formed by the plurality of packaged LED units 112 arranged in this way can be used as the display area 110 of the display module 11.

Step 103: Disposing a plurality of second LED chips on at least one side of the plurality of packaged LED units to the substrate to obtain a display module.

A plurality of second LED chips 122 are arranged on the substrate on at least one side of the plurality of packaged LED units 112. The area where the plurality of second LED chips 122 are located can be used as the splicing area 120 of the display module 11. A position close to one side or multiple sides of the display area 110 can be used as the splicing area 120 of the display module 11. A plurality of second LED chips 122 may be arranged in the splicing area 120. For example, the plurality of second LED chips 122 may be arranged in a line in the splicing area 120. Moreover, the splicing area 120 may only be provided with a plurality of second LED chips 122 in one column or one row. Thereby, the distance between the plurality of second LED chips 122 in the splicing area 120 of the two display modules 11 can be set as required, without being affected by the packaging frame 1123. In turn, the screen display at the splicing location of the splicing screen 10 is consistent or uniform with the screen display in the display area 110, which solves the problem of poor display performance of the existing splicing screen.

Step 104: Splicing a plurality of the display modules so that in a splicing direction, there is a first distance between each of the second LED chips and the first LED chip of an adjacent packaged LED unit, there is a second distance between the first LED chip in the packaged LED unit and the first LED chip in the adjacent packaged LED unit, and the second distance is greater than the first distance.

It should be noted that the area between the display area 110 and the chip film can be used as the splicing area 120, because this part reserves an area for binding. Therefore, the spacing between the pixel units in this part of the area is relatively large. In the embodiment of the present application, a single second LED chip 122 is arranged in this part of the area to reduce the spacing between the pixel units at the splicing site. In turn, the display performance of the splicing screen 10 is improved. Of course, the arrangement positions of the plurality of second LED chips 122 and the corresponding splicing area 120 and display area 110 may also have other forms, which will not be illustrated here.

Exemplarily, a plurality of display modules 11 may be spliced to form a splicing screen 10. For example, a plurality of display modules 11 may all be arranged on a body 20 with a larger size. Each display module 11 is correspondingly disposed on the body 20 to form a splicing screen 10 by splicing. Of course, there may be other ways of splicing multiple display modules 11, which will not be repeated here.

In the splicing screen 10, the manufacturing method thereof, and the display device 1 of the embodiment of the present application, the splicing screen 10 includes a plurality of display modules 11 spliced with each other. Each display module 11 may include a display area 110 and a splicing area 120. The splicing area 120 is disposed on at least one side of the display area 110. That is, the splicing area 120 of one display module 11 is adjacent to another display module 11. Each display module 11 also includes a plurality of packaged LED units 112 and a plurality of second LED chips 122. A plurality of packaged LED units 112 are arranged in the display area 110 of the display module 11. Each packaged LED unit 112 includes at least three first LED chips 1121. The plurality of second LED chips 122 are arranged in the splicing area 120. In the splicing direction X, there is a first distance between each second LED chip 122 and the first LED chip 1121 of the adjacent packaged LED unit 112. There is a second distance between one first LED chip 1121 in one packaged LED unit 112 and the first LED chip 1121 in the adjacent packaged LED unit 112. The second distance is greater than the first distance. That is, the distance between each second LED chip 122 and the first LED chip 1121 of the adjacent packaged LED unit 112 is less than the distance between two first LED chips 1121 arranged oppositely in two adjacent packaged LED units 112. The splicing direction X is the direction in which the two display modules 11 face the splicing or back to the separation. By arranging a single LED chip in the splicing area 120 of the display module 11. This allows the distance between the LED chips in the splicing area 120 of two adjacent display modules 11 to be set to a required size without being affected by the packaging. This makes the spliced display images of the display module 11 uniform, thereby improving the display performance of the splicing screen 10. In addition, by disposing the packaged LED unit 112 in the display area 110 of the display module 11, compared to disposing a single LED chip in the display area, the assembly speed of the display module 11 can be increased.

In the foregoing embodiments, the description of each embodiment has its own focus. For parts that are not described in detail in a certain embodiment, reference may be made to related descriptions of other embodiments.

In the description of this application, the terms “first” and “second” are only used for descriptive purposes, and cannot be understood as indicating or implying relative importance or implicitly indicating the number of indicated technical features. Thus, the features defined with “first” and “second” may explicitly or implicitly include one or more features.

The splicing screen, the manufacturing method thereof, and the display device provided by the embodiments of the present application have been described in detail above. Specific examples are used in this article to illustrate the principle and implementation of this application. The description of the above embodiments is only used to help understand the method and core idea of the present application. Further, for those skilled in the art, based on the idea of this application, there will be changes in the specific implementation and the scope of application. In summary, the content of this manual should not be construed as a limitation on this application.

What is claimed is:

1. A splicing screen, comprising:
a plurality of display modules that are spliced with each other, wherein each of the display modules comprises a display area and a splicing area located on at least one side of the display area, and each of the display modules comprises:
a plurality of packaged LED units disposed in the display area of the display module, wherein each packaged LED unit comprises at least three first LED chips;
a plurality of second LED chips disposed in the splicing area of the display module;
wherein in a splicing direction, there is a first distance between each of the second LED chips and the first LED chip of an adjacent packaged LED unit, there is a second distance between the first LED chip in the packaged LED unit and the first LED chip in the adjacent packaged LED unit, and the second distance is greater than the first distance.

2. The splicing screen according to claim 1, wherein each of the packaged LED units comprises a package frame and three of the first LED chips, the three first LED chips are disposed in one row and three columns in the package frame, and a row direction of the three first LED chips is perpendicular to the splicing direction.

3. The splicing screen according to claim 2, wherein the packaged LED units are disposed in an array of M rows and N columns, a row direction of the packaged LED units is perpendicular to the splicing direction, and at least three of the first LED chips in the packaged LED units in two adjacent rows are disposed in parallel.

4. The splicing screen according to claim 1, wherein the second LED chips in the splicing area are arranged in an array of one row and K columns, and a row direction of the second LED chips is perpendicular to the splicing direction.

5. The splicing screen according to claim 4, wherein each of the display modules comprises two splicing areas, and the two splicing areas are oppositely disposed on both sides of the display area.

6. The splicing screen according to claim 1, wherein in the splicing direction, there is a third distance between the second LED chip in one of the splicing areas and the second LED chip in the splicing area of an adjacent display module, and the third distance is equal to the second distance.

7. A display device, comprising:
a body; and
a splicing screen connected to the body, wherein the splicing screen comprises a plurality of display modules that are spliced with each other, each of the display modules comprises a display area and a splicing area located on at least one side of the display area, and each of the display modules comprises:
a plurality of packaged LED units disposed in the display area of the display module, wherein each packaged LED unit comprises at least three first LED chips;
a plurality of second LED chips disposed in the splicing area of the display module;
wherein in a splicing direction, there is a first distance between each of the second LED chips and the first LED chip of an adjacent packaged LED unit, there is a second distance between the first LED chip in the packaged LED unit and the first LED chip in the adjacent packaged LED unit, and the second distance is greater than the first distance.

8. The display device according to claim 7, wherein each of the packaged LED units comprises a package frame and three of the first LED chips, the three first LED chips are disposed in one row and three columns in the package frame, and a row direction of the three first LED chips is perpendicular to the splicing direction.

9. The display device according to claim 8, wherein the packaged LED units are disposed in an array of M rows and N columns, a row direction of the packaged LED units is perpendicular to the splicing direction, and at least three of the first LED chips in the packaged LED units in two adjacent rows are disposed in parallel.

10. The display device according to claim 7, wherein the second LED chips in the splicing area are arranged in an array of one row and K columns, and a row direction of the second LED chips is perpendicular to the splicing direction.

11. The display device according to claim 10, wherein each of the display modules comprises two splicing areas, and the two splicing areas are oppositely disposed on both sides of the display area.

12. The display device according to claim 7, wherein in the splicing direction, there is a third distance between the second LED chip in one of the splicing areas and the second LED chip in the splicing area of an adjacent display module, and the third distance is equal to the second distance.

13. A method of manufacturing a splicing screen, comprising:
packaging at least three first LED chips to obtain a packaged LED unit;
punching a plurality of the packaged LED units on a substrate;
disposing a plurality of second LED chips on at least one side of the plurality of packaged LED units to the substrate to obtain a display module;
splicing a plurality of the display modules so that in a splicing direction, there is a first distance between each of the second LED chips and the first LED chip of an adjacent packaged LED unit, there is a second distance between the first LED chip in the packaged LED unit and the first LED chip in the adjacent packaged LED unit, and the second distance is greater than the first distance.

14. The method according to claim 13, wherein packaging the at least three first LED chips to obtain the packaged LED unit comprises:
arranging the three first LED chips in a row and three columns in a packaging frame to form the packaged LED unit, wherein a row direction of the three first LED chips is perpendicular to the splicing direction.

15. The method according to claim 14, wherein punching the plurality of the packaged LED units on the substrate comprises:
arranging a plurality of the packaged LED units in an array of M rows and N columns, wherein a row direction of the plurality of packaged LED units is perpendicular to the splicing direction, and at least three of the first LED chips in the packaged LED units of two adjacent rows are arranged in parallel.

16. The method according to claim 13, wherein disposing the plurality of second LED chips on the at least one side of the plurality of packaged LED units to the substrate to obtain the display module comprises:
arranging the plurality of second LED chips in an array of one row and K columns, and a row direction of the plurality of the second LED chips is perpendicular to the splicing direction.

17. The method according to claim 16, wherein disposing the plurality of second LED chips on the at least one side of the plurality of packaged LED units to the substrate to obtain the display module further comprises:
arranging the plurality of second LED chips on opposite sides of the plurality of packaged LED units, respectively.

18. The method according to claim 13, wherein after splicing the plurality of the display modules, the method further comprises:
splicing a completed display module, wherein in the splicing direction, there is a third distance between the second LED chip in one of the splicing areas and the second LED chip in the splicing area of an adjacent display module, and the third distance is equal to the second distance.

19. The method according to claim 13, wherein disposing the plurality of second LED chips on the at least one side of the plurality of packaged LED units to the substrate to obtain the display module further comprises:
splicing different numbers of the display modules to obtain spliced screens having different sizes.

20. The method according to claim 13, wherein the display module comprises a flip chip film, and disposing the plurality of second LED chips on the at least one side of the plurality of packaged LED units to the substrate to obtain the display module further comprises:
arranging the plurality of the second LED chips between the plurality of packaged LED units and the flip chip film.
